(19) United States
(12) Patent Application Publication
(10) Pub. No.: US 2011/0295536 A1
(43) Pub. Date: Dec. 1, 2011

(54) CLOCK JITTER ANALYZING METHOD AND APPARATUS

(75) Inventors: Tomoyuki YODA, Kawasaki-Shi (JP); Takuma AOYAMA, Fujisawa-Shi (JP); Sachio HAYASHI, Kawasaki-Shi (JP)

(73) Assignee: KABUSHIKI KAISHA TOSHIBA, Tokyo (JP)

(21) Appl. No.: 12/982,739

(22) Filed: Dec. 30, 2010

(30) Foreign Application Priority Data
May 31, 2010 (JP) 2010-124345

(51) Int. Cl. G06F 19/00; G01R 29/00

(52) U.S. Cl. 702/69

(57) ABSTRACT

There is provided a method for analyzing a jitter of a clock flowing in a clock path inside a semiconductor integrated circuit. Elements, which belong to any clock domains except for a selected clock domain among operation scenario information, are brought into a halting state, to create a domain operation scenario. Using the domain operation scenario, a power-supply noise analysis is performed on a clock used in the selected clock domain for a period of one to several cycles, to obtain a domain power-supply noise waveform. The obtained waveform is repeatedly connected, to create a cyclic waveform. Part of the cyclic waveform is halted, to obtain a processed domain power-supply noise waveform. The processed domain power-supply noise waveform obtained with respect to each clock domain is superimposed, to create a power-supply noise waveform. Based on the created waveform, a jitter of the clock flowing in the clock path is calculated.

### CROSS-REFERENCE TO RELATED APPLICATIONS

This application is based upon and claims the benefit of priority from the prior Japanese Patent Application No. 2010-124345, filed on May 31, 2010, the entire contents of which are incorporated herein by reference.

### FIELD

Embodiments described herein relate generally to a clock jitter analyzing method and an apparatus for executing the method.

### BACKGROUND

With recent development of finer and faster processing on a semiconductor integrated circuit (hereinafter also simply referred to as “circuit”), there is an increase in influence exerted by a power-supply noise on a circuit operation. The power-supply noise is attributed, for example, to a voltage drop that occurs in a power wire or a ground wire commonly connected with a plurality of digital circuit elements (hereinafter simply referred to as “elements”) at the time of operation of the elements. A voltage applied to the element fluctuates due to the power-supply noise, to cause a change in operating speed of the element, resulting in occurrence of a jitter (hereinafter referred to as clock jitter) in a clock that passes through a clock path made up of the element. There are a variety of kinds of clock jitters, and among them, for example, a clock jitter called a cycle jitter is determined according to a difference between the time for passage of a given clock (first clock) in the clock path inside a semiconductor integrated circuit and the time for passage of a next clock (second clock) in the clock path. Other clock jitters also become worse when the time for passage in the clock path fluctuates, as does the cycle jitter.

As thus described, the clock jitter that occurs due to the power-supply noise causes an unexpected timing error. Therefore, in order to prevent erroneous operation of the circuit, it is necessary to design timing in previous consideration of a clock jitter, especially a worst value of the clock jitter.

Further, as one of specifications (e.g. memory interface such as DDR) for connection between the semiconductor integrated circuit and an external semiconductor device, the worst value of the clock jitter is often defined.

Therefore, grasping the worst value of the clock jitter at the designing stage is important.

Generally, the clock jitter is calculated by two steps which are a power-supply noise analysis and a clock jitter analysis performed using a result of the former analysis. Therebetween, the power-supply noise analysis is performed on the whole of a large-scale semiconductor integrated circuit including a plurality of clock domains, and thus requires very long calculation time. On the other hand, the clock jitter analysis may be performed only on a circuit made up of elements included in the clock path as a target of the jitter analysis, and hence the analysis completes in a much short time as compared with the power-supply noise analysis. Therefore, the time required for the power-supply noise analysis takes up most of the clock jitter calculation time.

The clock jitter becomes worst only for a small amount of time out of the circuit operation time. Accordingly, since calculating the worst value of the clock jitter requires the analysis of the power-supply noise on the circuit over long periods, it takes an immense amount of calculation time, and has thus not been realistic.

### BRIEF DESCRIPTION OF THE DRAWINGS

FIG. 1 is a flowchart showing a procedure for a clock jitter analysis according to an embodiment of the present invention;

FIG. 2 is a diagram showing an example of domain operation scenario information;

FIG. 3 is a waveform diagram for explaining a power-supply noise waveform processing method;

FIG. 4 is a waveform diagram showing processed power-supply noise waveforms of two clock domains, and a power-supply noise waveform obtained by superimposing those; and

FIG. 5 is a diagram showing a schematic configuration of a clock jitter analyzing apparatus according to the present embodiment, and information that is input from the outside of the apparatus.

### DETAILED DESCRIPTION

According to an embodiment, there is provided a method for analyzing a jitter of a clock flowing in a clock path inside a semiconductor integrated circuit having a plurality of clock domains. First, one clock domain is selected from among the plurality of clock domains. Next, elements, which belong to any clock domains except for the selected clock domain among operation scenario information indicating a transition timing and a transition direction of an output signal with respect to each element inside the semiconductor integrated circuit, are brought into a halting state, thereby to create a domain operation scenario. Next, by use of the domain operation scenario, a power-supply noise analysis is performed on a clock used in the selected clock domain for a period of one to several cycles, thereby to obtain a domain power-supply noise waveform that is generated by only the selected clock domain being operated. Next, the domain power-supply noise waveform is repeatedly connected to create a cyclic waveform, and part of the cyclic waveform is halted to obtain a processed domain power-supply noise waveform having a noise halting period that is longer than a cycle of the clock flowing in the clock path. Next, the processed domain power-supply noise waveform obtained with respect to each of the plurality of clock domains is superimposed, thereby to create a power-supply noise waveform having a noise halting period that is longer than the cycle of the clock flowing in the clock path. Based on the power-supply noise waveform, a jitter of the clock flowing in the clock path is calculated.

As described above, it has hitherto been not easy to calculate a worst value of a clock jitter due to the time required for the power-supply noise analysis being very long.

Thereat, in the embodiment of the present invention, the power-supply noise analysis is performed with respect to each clock domain for such a short period as one clock (or several clocks). A waveform as a result of each analysis is then processed. Thereafter, those processed waveforms are superimposed, to create a power-supply noise waveform which gives the worst value of a clock jitter. Using this power-supply noise waveform, a clock jitter is calculated.

Hereinafter, a clock jitter analyzing method according to the embodiment of the present invention, and a clock jitter analyzing apparatus for executing the method are described.

In the clock jitter analyzing method according to the present embodiment, information given from the outside includes clock domain information, element clock domain information, operation scenario information, circuit layout information, cell power consumption information, clock information, and clock pass information. These pieces of information are detailed below.

The clock domain information is information including a clock domain name and a frequency of a clock used in the clock domain. This clock domain information is described in a format of SDC (Synopsys Design Constraint) or the like, and may include information (operation timing information) concerning clock operation start time.

The element clock domain information is information indicating which clock domain each element (instance) inside the circuit belongs to. This element clock domain information can be output with a Static Timing Analysis (STA) tool or the like.

The operation scenario information is information indicating a transition timing of an output signal of the element and a transition direction (rise/fall) of the output signal with respect to each element inside the circuit. This operation scenario information is described, for example, in a format of VCD (Value Change Dump) or the like.

The circuit layout information is information concerning a layout of each element inside the circuit, a connecting relation among the elements, wiring, and the like. This circuit layout information is described, for example, in a format such as DEF (Design Exchange Format), LEF (Library Exchange Format), or the like.

The cell power consumption information is information required for calculating power consumption of a cell (type of element) in the circuit and described, for example, in a format of Liberty, SPICE netlist, or the like.

The clock information is information concerning a cycle and a delay amount of a clock in a clock path as an object of the clock jitter analysis. It is to be noted that the clock delay amount included in this clock information is a delay amount in the case without a power-supply noise.

The clock path information is information concerning an element and wiring that constitute the clock path as the object of the clock jitter analysis and described, for example, in a format of SPICE netlist, or the like.

Next described is a clock jitter analyzing method according to the present embodiment, that is performed using the above information.

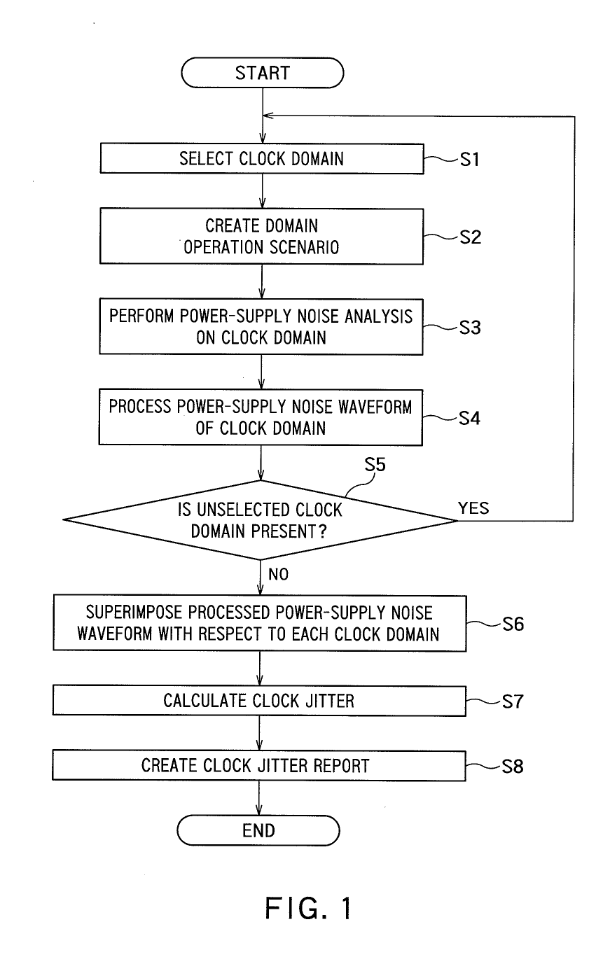

As shown in a flowchart of FIG. 1, a procedure for the clock jitter analysis according to the present embodiment includes a step of selecting a clock domain (S1), a step of creating an operation scenario of the clock domain (domain operation scenario) (S2), a step of performing a power-supply noise analysis on the clock domain (S3), a step of processing a power-supply noise waveform of the clock domain (S4), a step of determining the presence or absence of an unselected clock domain (S5), a step of superimposing the processed power-supply noise waveform with respect to each clock domain (S6), a step of calculating a clock jitter by use of the superimposed power-supply noise waveform (S7), and a step of creating a clock jitter report (S8).

Next, processing in each step is detailed along FIG. 1.

(1) First, one unselected clock domain is selected from among a plurality of clock domains in clock domain information (Step S1).

(2) Next, a domain operation scenario for use in power-supply noise analysis in the selected clock domain is created based on a name (referred to as clock domain name) of the clock domain selected in Step S1, the element clock domain information and the operation scenario information (Step S2).

This domain operation scenario is created by bringing all elements, which belong to any clock domains except for the selected clock domain among the operation scenario information, into a “halting” state. It is to be noted that the “halting” state means a state where the element does not transit, namely an input signal of the element is fixed to “0” or “1”.

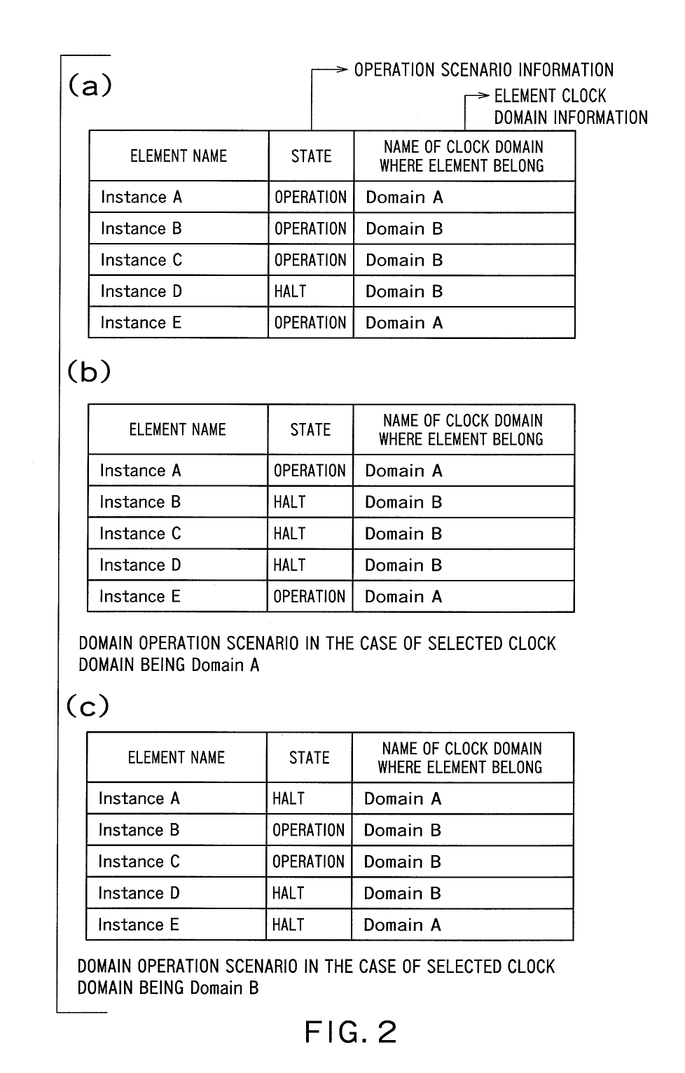

FIG. 2 shows an example of the domain operation scenario. In this example, in the circuit, five elements (Instances A to E) are provided and two clock domains (Domain A, Domain B) are present. FIG. 2(a) is a diagram obtained based on the operation scenario information and the element clock domain information, and indicates a clock domain which each element belongs to and a state of each element at a given time. Using this information, the domain operation scenario is created.

Specifically, in the case of the selected clock domain being Domain A, among elements (Instances B to D) belonging to the clock domain Domain B, elements (Instances B, C) in an “operating” state are brought into the “halting” state, thereby to create the domain operation scenario in the case of Domain A being selected as shown in FIG. 2(b).

On the other hand, in the case of the selected clock domain being Domain B, among elements (Instances A, E) belonging to the clock domain Domain A, elements, Instances A, E, in the “operating” state are brought into the “halting” state, thereby to create the domain operation scenario in the case of Domain B being selected as shown in FIG. 2(c).

As thus described, the domain operation scenario is obtained by halting the states of elements belonging to any clock domains except for the selected domain, and is an operation scenario that gives a condition where only the selected clock domain operates.

(3) Next, a power-supply noise analysis is performed on the selected clock domain based on the domain operation scenario information, the clock domain information, the circuit layout information, and the cell power consumption information (Step S3). This power-supply noise analysis is performed on a clock used in the selected clock domain for a period of one to several cycles. As a result, a power-supply noise waveform (referred to as domain power-supply noise waveform) is obtained which is generated by only the selected clock domain being operated. It should be noted that the power-supply noise analysis can also be performed using a commercially available power-supply noise analysis tool.

(4) Next, a domain power-supply noise waveform is processed based on information on the domain power-supply noise waveform and the clock information (Step S4).

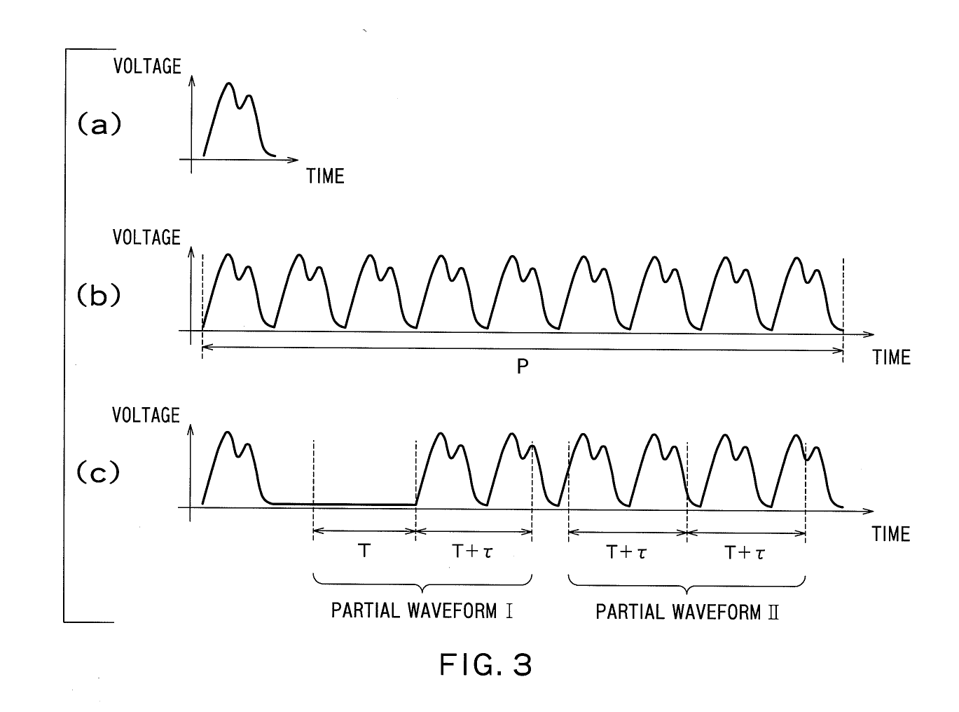

FIG. 3 is a diagram for explaining a power-supply noise waveform processing method. FIG. 3(a) shows an example of a domain power-supply noise waveform obtained by performing the power-supply noise analysis for a period of one cycle of a clock used in the selected clock domain. Taking this waveform as an example, a domain power-supply noise waveform processing method in the present step is described.

First, the domain power-supply noise waveform is repeatedly connected until a length of the waveform becomes larger than a least common multiple of clock cycles of the respective clock domains. Thereby, a cyclic waveform with a waveform length P shown in FIG. 3(b) is created.

Previously creating a waveform longer than a least common multiple of clock cycles of the respective clock domains as thus described can give a power-supply noise waveform including a power-supply noise variation expanded due to a difference in clock cycle in a later step of Step S6 (superimposition of waveforms).

Next, the above cyclic waveform is halted for a longer period than the cycle of the clock in the clock path as an object of the jitter analysis. Namely, a voltage of the waveform is dropped to a ground potential. Thereby, a processed domain power-supply noise waveform is obtained. As shown in FIG. 3(c), this processed domain power-supply noise waveform includes a partial waveform I in which a noise halting period that is longer than a clock cycle (T) in the clock path as the object of the jitter analysis, and a noise generation period that is longer than a sum (T+τ) of the clock cycle (T) and a delay amount (τ), are continued.

It is to be noted that in the partial waveform I, the noise halting period and noise generation period may be continued, and either period may be the first. τ is a delay amount of the clock in the clock path as the object of the jitter analysis. Therefore, the length (T+τ) represents the time from the clock being input into the clock path as the object of the jitter analysis to the clock completely getting out of the clock path.

Further, as shown in FIG. 3(c), the processed domain power-supply noise waveform includes a partial waveform II made up of a noise generation period loner than 2(T+τ).

The partial waveform I gives a condition where no power-supply noise is generated during passage of a first clock in the clock path and the power-supply noise keeps on being generated during passage of a following second clock in the clock path.

On the other hand, the partial waveform II gives a condition where the power-supply noise keeps on being generated during passage of both a first clock and a second clock in the clock path.

These two conditions give a maximal power-supply noise variation. As an intermediate condition, there is considered, for example, a condition where a power-supply noise is generated during 20% of the time for passage of a first clock, and a power-supply noise is generated during 80% of the time for passage of a second clock is considered, but in such an intermediate condition, the clock jitter does not become worst.

It is to be noted that the cyclic waveform may be processed so as to include at least either the partial waveform I or II in a plurality of number.

(5) Next, it is determined whether an unselected clock domain is present. In the case of Yes, the process returns to Step S1 and the processing according to the above steps S1 to S4, and in the case of No, the process goes to a following step S6 (Step S5).

(6) The processed domain power-supply noise waveform obtained with respect to each clock domain is superimposed (Step S6). Thereby, a power-supply noise waveform for use in the clock jitter analysis is created.

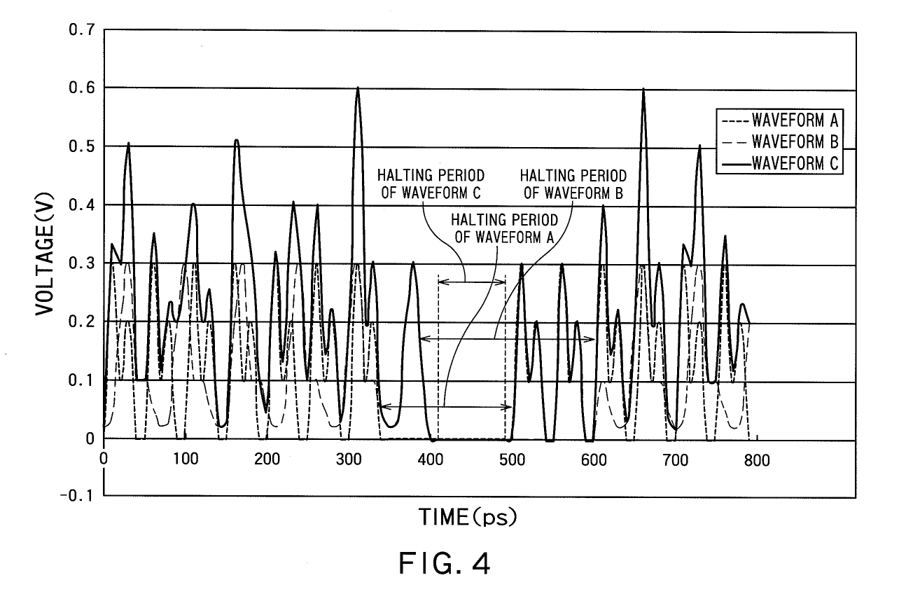

FIG. 4 shows a processed domain power-supply noise waveform (waveform A) of a clock domain, Domain A, with a clock cycle of 50 ps, a processed domain power-supply noise waveform (waveform B) of a clock domain, Domain B, with a clock cycle of 70 ps, and a power-supply noise waveform (waveform C) obtained by superimposing the waveform A and the waveform B. As shown in FIG. 4, the waveform C is required to have a noise halting period that is longer than the clock cycle T. Namely, the power-supply noise waveform is obtained by superimposing the processed domain power-supply noise waveforms such that a period when all the processed domain power-supply noise waveforms are halted is longer than the clock period T.

(7) Next, the clock jitter analysis is performed based on the information on the power-supply noise waveform obtained in Step S6 and the clock path information, to calculate a clock jitter (Step S7). This process can be performed, by use of a circuit analysis tool such as the SPICE simulator, or the like.

(8) Next created is a clock jitter report indicating a clock jitter calculation result (this result includes a worst value of the clock jitter) obtained in Step S7 (Step S8). This clock jitter report is preferably created in a format easy to understand for a circuit designer (e.g. graphical display of a clock jitter amount).

As described above, in the clock jitter analyzing method according to the present embodiment, the power-supply noise analysis may be performed on a clock used in the selected clock domain for such a very short period as one to several cycles, with respect to each selected clock domain. Therefore, according to the present embodiment, the worst value of the clock jitter can be calculated in a short time.

Next, a clock jitter analyzing apparatus for executing the foregoing clock jitter analyzing method is described.

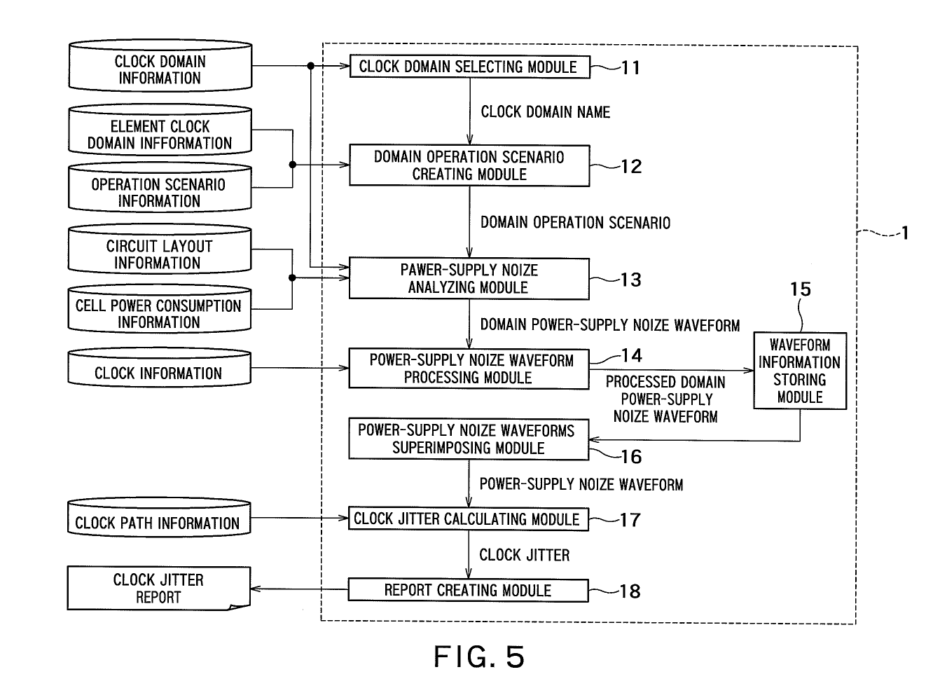

FIG. 5 shows a schematic configuration of a clock jitter analyzing apparatus according to the present embodiment, and information that is input into the clock jitter analyzing apparatus.

As shown in FIG. 5, a clock jitter analyzing apparatus 1 includes a clock domain selecting module 11, a domain operation scenario creating module 12, a power-supply noise analyzing module 13, a power-supply noise waveform processing module 14, a waveform information storing module 15, a power-supply noise waveforms superimposing module 16, a clock jitter calculating module 17, and a report creating module 18.

Hereinafter, each constitutional element is detailed.

The clock domain selecting module 11 selects one unselected clock domain among a plurality of clock domains present in clock domain information, and outputs the selected clock domain name.

The domain operation scenario creating module 12 creates the foregoing domain operation scenario based on the clock domain name selected by the clock domain selecting module 11, the element clock domain information, and the operation scenario information.

The power-supply noise analyzing module 13 performs a power-supply noise analysis on the selected clock domain based on the domain operation scenario information, the clock domain information, the circuit layout information and the cell power consumption information, to obtain a domain power-supply noise waveform as a power-supply noise waveform generated by only the selected clock domain being operated in the semiconductor integrated circuit.

The power-supply noise waveform processing module 14 processes the domain power-supply noise waveform in the manner as described above based on the clock information (cycle, delay amount), and stores information on the processed domain power-supply noise waveform, obtained by the processing, into the waveform information storing module 15.

The power-supply noise waveforms superimposing module 16 reads information on the processed domain power-supply noise waveform of each clock domain which is stored in the waveform information storing module 15, and then superimposes the processed domain power-supply noise waveform obtained with respect to each clock domain, whereby a power-supply noise waveform for use in the foregoing clock jitter analysis is created.

The clock jitter calculating module 17 calculates a clock jitter by use of information on the power-supply noise waveform, output from the power-supply noise waveforms superimposing module 16, and the clock path information.

The report creating module 18 creates a clock jitter calculation report by use of a clock jitter calculation result (including the worst value of the clock jitter) output by the clock jitter calculating module 17, and outputs the report to the outside of the clock jitter analyzing apparatus 1.

Hereinbefore, the descriptions have been given to the clock jitter analyzing method and device according to the present embodiment.

The clock jitter analyzing method according to the present embodiment may be configured as a program to be executed by a computer. Further, such a program may be recorded into a recording medium readable by a computer, such as a CD-ROM, so as to be made distributable.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A clock jitter analyzing method for analyzing a jitter of a clock flowing in a clock path inside a semiconductor integrated circuit having a plurality of clock domains, the method comprising:
selecting one clock domain from among the plurality of clock domains;
bringing elements, which belong to any clock domains except for the selected clock domain among operation scenario information indicating a transition timing and a transition direction of an output signal with respect to each element inside the semiconductor integrated circuit, into a halting state, thereby to create a domain operation scenario;
performing, by use of the domain operation scenario, a power-supply noise analysis on a clock used in the selected clock domain for a period of one to several cycles, thereby to obtain a domain power-supply noise waveform that is generated by only the selected clock domain being operated;
repeatedly connecting the domain power-supply noise waveform to create a cyclic waveform, and halting part of the cyclic waveform to obtain a processed domain power-supply noise waveform having a noise halting period that is longer than a cycle of the clock flowing in the clock path;
superimposing the processed domain power-supply noise waveform obtained with respect to each of the plurality of clock domains, thereby to create a power-supply noise waveform having a noise halting period that is longer than the cycle of the clock flowing in the clock path; and
calculating a jitter of the clock flowing in the clock path by use of the power-supply noise waveform.

2. The clock jitter analyzing method of claim 1, wherein a length of the cyclic waveform is larger than a least common multiple of cycles of respective clocks in the plurality of clock domains.

3. The clock jitter analyzing method of claim 2, wherein the processed domain power-supply noise waveform includes:
a first partial waveform in which a noise halting period that is longer than the cycle of the clock flowing in the clock path, and a noise generation period that is longer than a sum of the cycle of the clock flowing in the clock path and a delay amount, are continued; and
a second partial waveform which is made up of a noise generation period that is longer than double the sum of the cycle of the clock flowing in the clock path and the delay amount.

4. The clock jitter analyzing method of claim 3, wherein the clock jitter is calculated using a SPICE simulator.

5. The clock jitter analyzing method of claim 3, wherein, after calculation of the clock jitter, a clock jitter report including a worst value of the jitter is created.

6. The clock jitter analyzing method of claim 3, wherein the operation scenario information is described in a Value Change Dump (VCD) format.

7. The clock jitter analyzing method of claim 1, wherein the processed domain power-supply noise waveform includes:
a first partial waveform in which a noise halting period that is longer than the cycle of the clock flowing in the clock path, and a noise generation period that is longer than a sum of the cycle of the clock flowing in the clock path and a delay amount, are continued; and
a second partial waveform which is made up of a noise generation period that is longer than double the sum of the cycle of the clock flowing in the clock path and the delay amount.

8. The clock jitter analyzing method of claim 7, wherein the clock jitter is calculated using a SPICE simulator.

9. The clock jitter analyzing method of claim 7, wherein, after calculation of the clock jitter, a clock jitter report including a worst value of the jitter is created.

10. The clock jitter analyzing method of claim 7, wherein the operation scenario information is described in a Value Change Dump (VCD) format.

11. The clock jitter analyzing method of claim 1, wherein the clock jitter is calculated using a SPICE simulator.

12. The clock jitter analyzing method of claim 1, wherein, after calculation of the clock jitter, a clock jitter report including a worst value of the jitter is created.

13. The clock jitter analyzing method of claim 1, wherein the operation scenario information is described in a Value Change Dump (VCD) format.

14. A clock jitter analyzing apparatus for calculating a jitter of a clock flowing in a clock path inside a semiconductor integrated circuit having a plurality of clock domains, the apparatus comprising:
a clock domain selecting module configured to select one clock domain from among the plurality of clock domains;
a domain operation scenario creating module configured to bring elements, which belong to any clock domains except for the selected clock domain among operation scenario information indicating a transition timing and a transition direction of an output signal with respect to each element inside the semiconductor integrated circuit, into a halting state, thereby to create a domain operation scenario;
a power-supply noise analyzing module configured to perform, by use of the domain operation scenario, a power-supply noise analysis on a clock used in the selected clock domain for a period of one to several cycles, thereby to obtain a domain power-supply noise waveform that is generated by only the selected clock domain being operated;
a power-supply noise waveform processing module configured to repeatedly connect the domain power-supply noise waveform to create a cyclic waveform, and halting part of the cyclic waveform to obtain a processed domain power-supply noise waveform having a noise halting period that is longer than a cycle of the clock flowing in the clock path;
a power-supply noise waveforms superimposing module configured to superimpose the processed domain power-supply noise waveform obtained with respect to each of the plurality of clock domains, thereby to create a power-supply noise waveform having a noise halting period that is longer than the cycle of the clock flowing in the clock path; and
a clock jitter calculating module configured to calculate a jitter of the clock flowing in the clock path by use of the power-supply noise waveform.

15. The clock jitter analyzing apparatus of claim 14, wherein a length of the cyclic waveform is larger than a least common multiple of cycles of respective clocks in the plurality of clock domains.

16. The clock jitter analyzing apparatus of claim 15, wherein the processed domain power-supply noise waveform includes:
a first partial waveform in which a noise halting period that is longer than the cycle of the clock flowing in the clock path, and a noise generation period that is longer than a sum of the cycle of the clock flowing in the clock path and a delay amount, are continued; and
a second partial waveform which is made up of a noise generation period that is longer than double the sum of the cycle of the clock flowing in the clock path and the delay amount.

17. The clock jitter analyzing apparatus of claim 16, wherein the clock jitter calculating module calculates the clock jitter by use of a SPICE simulator.

18. The clock jitter analyzing apparatus of claim 16, further comprising
a report creating module configured to create a clock jitter report including a worst value of the jitter based on the calculated clock jitter.

19. The clock jitter analyzing apparatus of claim 16, wherein the operation scenario information is described in a Value Change Dump (VCD) format.

20. The clock jitter analyzing apparatus of claim 14, wherein the processed domain power-supply noise waveform includes:
a first partial waveform in which a noise halting period that is longer than the cycle of the clock flowing in the clock path, and a noise generation period that is longer than a sum of the cycle of the clock flowing in the clock path and a delay amount, are continued; and
a second partial waveform which is made up of a noise generation period that is longer than double the sum of the cycle of the clock flowing in the clock path and the delay amount.
